(19) United States
(12) Patent Application Publication
(10) Pub. No.: US 2010/0319772 A1
(43) Pub. Date: Dec. 23, 2010

(54) THIN FILM SOLAR CELL WITH LIGHT TRANSMISSION

(76) Inventors: Chun-Hsiung Lu, Houli Township (TW); Wei-Tse Hsu, Houli Township (TW)

Correspondence Address: SINORICA, LLC, 2275 Research Blvd., Suite 500, ROCKVILLE, MD, 20850, US

(21) Appl. No.: 12/796,837

(22) Filed: Jun. 9, 2010

(30) Foreign Application Priority Data
Jun. 22, 2009 (TW) 098120818

(51) Int. Cl. H01L 31/00

(52) U.S. Cl. 136/258; 136/259

(57) ABSTRACT

The present invention relates to a thin film solar cell with light transmission. The thin film solar cell comprises a substrate, a front electrode layer, an absorption layer, a back electrode layer, a light-transmittance enhancing layer and an encapsulation layer, stacked in a sequence. Part of the back electrode layer is removed in depth so as to form a plurality of light-transmittance regions. Part of the light-transmittance enhancing layer and part of the encapsulation layer are disposed within each light-transmittance region. The light-transmittance enhancing layer has a refractive index between that of a first medium overlaid by the part of the light-transmittance enhancing layer disposed within each light-transmittance region and that of a second medium overlaying the part of the light-transmittance enhancing layer disposed within each light-transmittance region.

### FIELD OF THE INVENTION

The present invention relates to a solar cell, and more particularly to a thin film solar cell having enhanced photoelectric conversion efficiency by increasing photo-absorption rate in a semiconductor layer of the thin film solar cell.

### DESCRIPTION OF PRIOR ART

Solar cells is a clean and environment-friendly device of energy conversion. Conventional solar cells includes crystalline silicon solar cells, amorphous silicon solar cells, III-V compound solar cells and II-VI compound solar cells based on their semiconductor materials. The conventional solar cell comprises a substrate, a front electrode layer, an absorption layer and a back electrode layer. The front electrode layer can be formed of TCO material. The back electrode layer can be formed of metal material. The absorption layer can be formed of a p-n diode structure. When an incident light enter the p-n diode structure to generate electron-hole pairs, the electrons and holes respectively move to two opposite directions by means of the built-in electrical field so as to output a voltage from two terminals of electrodes.

Typically, the solar cell can be provided on the roof of buildings or other locations where it is easy to receive the sunlight. However, when the solar cell is disposed in the glass curtain wall to receive the sunlight, if the solar cell has a back electrode layer of metal material, then the sunlight cannot pass through the back electrode layer due to its metal material so as to limit the application of the solar cell.

For the sake of improving the afore-mentioned drawbacks of the solar cell, a see-through solar cell is provided. U.S. Pat. No. 6,858,461 discloses a photovoltaic module having partially see-through structure shown in FIG. 1, the photovoltaic module 110 comprises a substrate 114, a front electrode layer 118, a photo-conversion layer 120 and a back electrode layer 122. The photo-conversion layer 120 and a back electrode layer 122 can be formed by means of laser scribing to form a plurality of grooves 140 such that the photovoltaic module 110 achieves the purpose of partially see-through structure. Besides, U.S. Pat. No. 4,795,500 discloses a photovoltaic device shown in FIG. 2 that comprises a transparent substrate 1, a front electrode layer 3, a photoactive semiconductor layer 4 and a metallic back electrode 5 where the metallic back electrode 5 is scribed to from a plurality of holes 6 each of which is extended through the metallic back electrode 5 to the photoactive semiconductor layer 4 so as to achieve the purpose of light transmittance.

In the aforesaid disclosures, the light transmittance of the solar cell can be improved by scribing the see-through grooves or holes but the effect of improving the light transmittance is limit. Besides, too many see-through grooves or holes may remove more area of the photo-conversion layer in order to increase the light transmittance of the solar cell such that the solar cell has a poor effect of photoelectric conversion. Therefore, the scribing area and the number of see-through grooves or holes needs to be restricted in order to maintain a certain level of photoelectric conversion. A need exists for providing a thin film solar cell with a see-through structure while maintaining an improved photoelectric conversion.

### SUMMARY OF THE INVENTION

In light of the aforesaid problems, a thin film solar cell with light transmission has been disclosed in the invention so as to achieve the purpose of improving the light transmission by means of providing a layer of material with a predetermined refractive index within a light-transmittance region.

In order to achieve the afore-mentioned purpose, the present invention provides a thin film solar cell that comprises a substrate, a front electrode layer, an absorption layer, a back electrode layer, a light-transmittance enhancing layer and an encapsulation layer wherein at least the back electrode layer comprises a plurality of light-transmittance regions that are extended to the absorption layer or the front electrode layer from the back electrode layer. Part of the light-transmittance enhancing layer and part of the encapsulation layer are being disposed within each of the light-transmittance regions wherein part of the encapsulation layer is filled in the light-transmittance region, and wherein the light-transmittance enhancing layer has a refractive index between the refractive index of a first medium overlaid by the part of said light-transmittance enhancing layer disposed within each light-transmittance region and the refractive index of a second medium overlaying the part of the light-transmittance enhancing layer disposed within each light-transmittance region. The light-transmittance enhancing layer can overlay the absorption layer or the front electrode layer and the encapsulation layer can overlay the light-transmittance enhancing layer. The light-transmittance enhancing layer has a refractive index between 1 and 4. Therefore, the light-transmittance enhancing layer having the predetermined refractive index is provided to guide an incident light pass through the absorption layer or the back electrode layer into the inside room so as to improve the light-transmittance of the thin film solar cell.

Besides, the encapsulation layer is formed of a material selected from the group consisting of ethylene vinyl acetate copolymer (EVA) and polyvinyl butyral (PVB). The absorption layer is formed of a material selected from the group consisting of amorphous silicon (a-Si), polycrystalline silicon (poly-Si), microcrystalline silicon (mc-Si) and microcrystalline silicon germanium (mc-SiGe). The absorption layer is formed of cadmium telluride (CdTe). The front electrode layer is formed of transparent conducting oxide (TCO) that is selected from the group consisting of SnO2, ITO, IZO, AZO, BZO, GZO and ZnO. The substrate is selected from the group consisting of glass, quartz, transparent plastics, transparent polymer and flexible substrate. The substrate is selected from the group consisting of soda lime glass (SLG), low iron class and alkali free glass if the substrate is a transparent glass substrate. The back electrode layer is formed of metal selected from the group consisting of aluminum (Al), nickel (Ni), gold (Au), silver (Ag), chromium (Cr), titanium (Ti) and palladium (Pd).

Since the refractive index of the light-transmittance enhancing layer can be determined from the refractive index of the medium overlaid by the light-transmittance enhancing layer, and the refractive index of the medium overlaying the light-transmittance enhancing layer so that the light transmittance of the incident light within the light-transmittance region is improved to increase the light transmittance quantity passing through the absorption layer or the back electrode layer so as to enhance the light transmittance of the film solar cell. Besides, the predetermined refractive index of the light-transmittance enhancing layer is provided in the thin film solar cell of the present invention so that the number of the light-transmittance regions is reduced to improve the light absorption of the absorption layer and to enhance the light transmission of the solar cell. Therefore, the present invention can resolve the problem of restricted application of the see-through solar cell and still maintain the photoelectric conversion efficiency.

Although a preferred embodiment of the invention has been described for purposes of illustration, it is understood that various changes and modifications to the described embodiment can be carried out without departing from the scope and the spirit of the invention as disclosed in the appended claims.

### BRIEF DESCRIPTION OF DRAWINGS

The structure and the technical means adopted by the present invention to achieve the above and other objectives can be best understood by referring to the following detailed description of the preferred embodiments and the accompanying diagrams.

FIG. 1 is a schematic view that shows a conventional photovoltaic module having partially see-through structure.

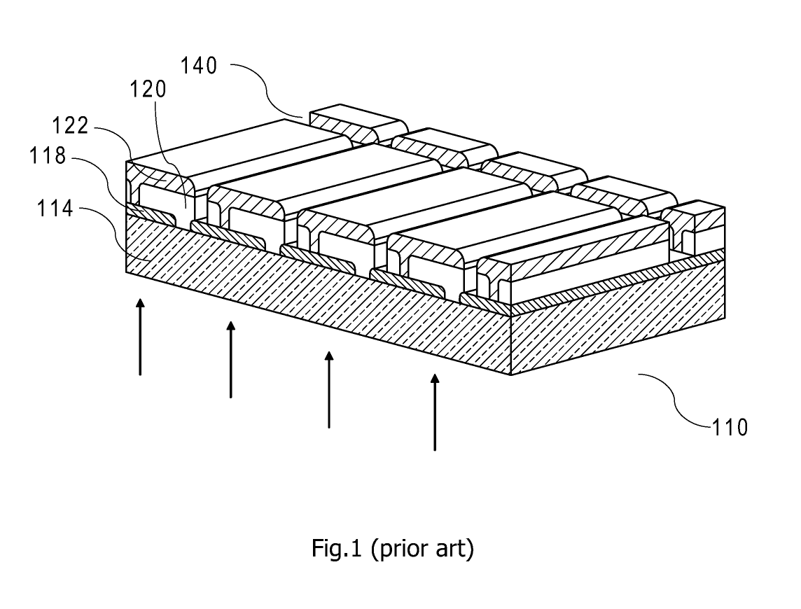

FIG. 2 is a schematic view that shows a conventional photovoltaic device.

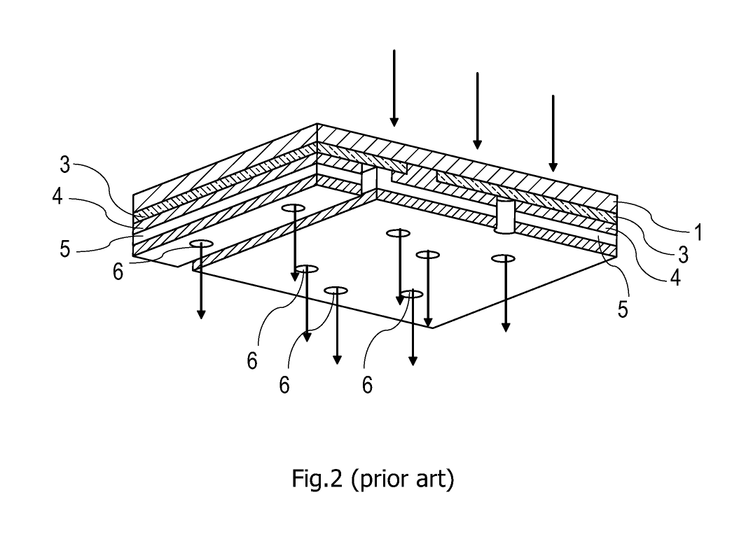

FIG. 3A is a sectional view that shows a thin film solar cell according to one preferred embodiment of the invention.

FIG. 3B is a sectional view that shows a thin film solar cell according to another preferred embodiment of the invention.

### DETAILED DESCRIPTION OF PREFERRED EMBODIMENTS

A thin film solar cell thereof has been disclosed in the invention; wherein the principles of photoelectric conversion employed in solar cell may be easily comprehended by those of ordinary skill in relevant technical fields, and thus will not be further described hereafter. Meanwhile, it should be noted that the drawings referred to in the following paragraphs only serve the purpose of illustrating structures related to the characteristics of the disclosure, and are not necessarily drawn according to actual scales and sizes of the disclosed objects.

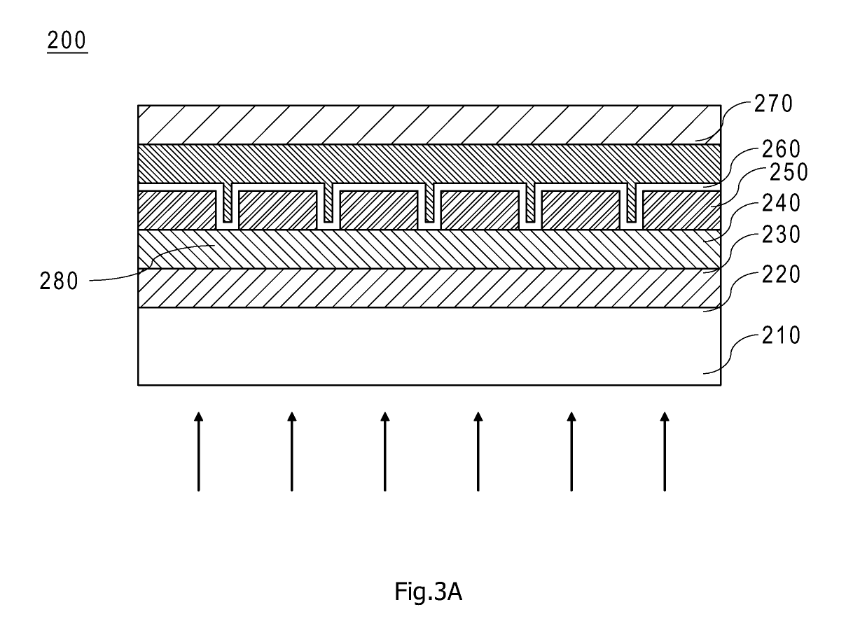

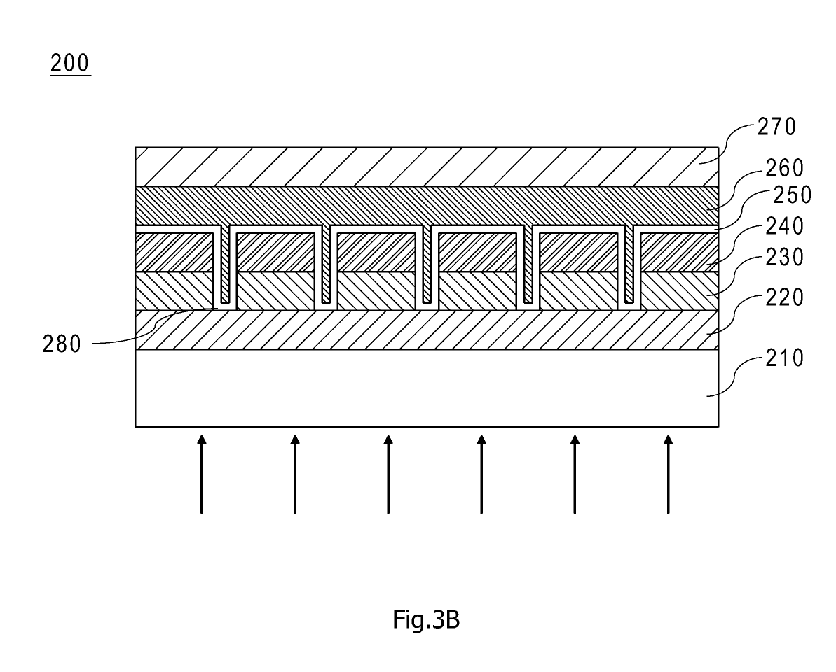

Refer to FIG. 3A, which is a sectional view that shows a thin film solar cell according to one preferred embodiment of the invention. The thin film solar cell 200 comprises a substrate 210, a front electrode layer 220, an absorption layer 230, a back electrode layer 240, a light-transmittance enhancing layer 250 and an encapsulation layer 260 stacked in such a bottom-up sequence from an incident side. The encapsulation layer 260 is further provided with a cover glass 270 disposed on the encapsulation layer 260. At least part of the back electrode layer 240 is removed in depth down to a boundary level between the back electrode layer 240 and the absorption layer 230 so as to form a plurality of light-transmittance regions 280. Part of the light-transmittance enhancing layer 250 and part of the encapsulation layer 260 are disposed within each of the light-transmittance regions 280, and more particularly, part of the encapsulation layer 260 is filled in the light-transmittance regions 280. The refractive index of the light-transmittance enhancing layer 250 can be determined from the refractive index of the medium's material overlaid by the light-transmittance enhancing layer 250, and the refractive index of the medium's material overlaying the light-transmittance enhancing layer 250. For example, the refractive index of the light-transmittance enhancing layer 250 has a value in a range between the refractive index of the medium (i.e. the absorption layer 230) overlaid by the light-transmittance enhancing layer 250 and the refractive index of the medium (i.e. the encapsulation layer 260) overlaying the light-transmittance enhancing layer 25, disposed within each light-transmittance region 280. That is to say, the refractive index of the light-transmittance enhancing layer 250 has a value in a range between the refractive index of the absorption layer 230 and the refractive index of the encapsulation layer 260, so as to improve the light transmittance of the incident light through the solar cell.

Besides, each light-transmittance region 280 can be further extended through the absorption layer 230 (shown in FIG. 3B) by further removing part of the absorption layer 230 in depth down to a boundary level between the absorption layer 230 and the front electrode layer 220. Besides, each light-transmittance region 280 can be extended through the absorption layer 230 and the front electrode layer 220 as well (not shown). In this case, the refractive index of the light-transmittance enhancing layer 250 has a value in a range between the refractive index of the medium (i.e. the front electrode layer 220) overlaid by the light-transmittance enhancing layer 250 and the refractive index of the medium (i.e. the encapsulation layer 260) overlaying the light-transmittance enhancing layer 25, disposed within each light-transmittance region 280. That is to say, the refractive index of the light-transmittance enhancing layer 250 has a value in a range between the refractive index of the front electrode layer 220 and the refractive index of the encapsulation layer 260, so as to improve the light transmittance of the incident light through the thin film solar cell.

On the other hand, each layer of the thin film solar cell 200 is formed of material(s) described as follows:

The substrate 210 is selected from the group consisting of glass, quartz, transparent plastics, transparent polymer and flexible substrate. When the substrate 210 is a transparent glass substrate, the substrate can be selected from the group consisting of soda lime glass (SLG), low iron class and alkali free glass

The front electrode layer 220 is formed of transparent conducting oxide (TCO) that is selected from the group consisting of SnO2, ITO, IZO, AZO, BZO, GZO and ZnO.

The absorption layer 230 is formed of a material selected from the group consisting of amorphous silicon (a-Si), polycrystalline silicon (poly-Si), microcrystalline silicon (mc-Si) and microcrystalline silicon germanium (mc-SiGe), or the absorption layer is formed of cadmium telluride (CdTe). It is noted that any material used in the superstrate-type thin film solar cell together with photoelectric conversion effect can be included in the present invention.

The back electrode layer 240 is formed of metal selected from the group consisting of aluminum (Al), nickel (Ni), gold (Au), silver (Ag), chromium (Cr), titanium (Ti) and palladium (Pd). Besides, any other conducting material can be included in the present invention.

The encapsulation layer 260 is formed of a material selected from the group consisting of ethylene vinyl acetate copolymer (EVA) and polyvinyl butyral (PVB).

The light-transmittance enhancing layer 250 has a predetermined refractive index in a range between the refractive index of the medium overlaid by the light-transmittance enhancing layer 250 and the refractive index of the medium overlaying the light-transmittance enhancing layer 250, disposed within each light-transmittance region 280. In the foregoing embodiments, the refractive index of the light-transmittance enhancing layer 250 has a value between 1 and 4. For example, silicon dioxide (SiO2) is a material having an refractive index of between 1 and 4.

Each layer of the thin film solar cell 200 can be formed in a conventional method so as to stacked in such a bottom-up sequence from an incident side. The conventional method may includes sputtering, atmosphere thermal chemical vapor deposition, low pressure chemical vapor deposition (LPCVD), electron cyclotron resonance chemical vapor deposition (ECR-CVD), D.C glow discharge, radio frequency glow discharge, hot filament chemical vapor deposition, and it should not be limited to the afore-mentioned methods. Besides, each light-transmittance region 280 can be formed by laser scribing. The light-transmittance enhancing layer 250 can be formed by chemical vapor deposition, physical vapor deposition, or coating to fill in the light-transmittance region 280.

For the forgoing descriptions, the light-transmittance enhancing layer 250 having the predetermined refractive index is provided to guide an incident light pass through the absorption layer or the back electrode layer into the inside room so as to improve the light-transmittance of the thin film solar cell. Therefore, it can achieve the purpose of improving the light transmission of the thin film solar cell.

Although a preferred embodiment of the invention has been described for purposes of illustration, it is understood that various changes and modifications to the described embodiment can be carried out without departing from the scope and the spirit of the invention as disclosed in the appended claims.

What is claimed is:

1. A thin film solar cell with light transmission, comprising a substrate, a front electrode layer, an absorption layer, a back electrode layer, a light-transmittance enhancing layer and an encapsulation layer stacked in a bottom-up sequence, wherein part of said back electrode layer is removed down to a boundary level between said back electrode layer and said absorption layer so as to form a plurality of light-transmittance regions, part of said light-transmittance enhancing layer and part of said encapsulation layer being disposed within each said light-transmittance region, said light-transmittance enhancing layer having a refractive index between that of a first medium overlaid by said part of said light-transmittance enhancing layer disposed within each said light-transmittance region and that of a second medium overlaying said part of said light-transmittance enhancing layer disposed within each said light-transmittance region.

2. The thin film solar cell with light transmission of claim 1, wherein said second medium is part of said encapsulation layer.

3. The thin film solar cell with light transmission of claim 1, wherein said first medium is part of said absorption layer.

4. The thin film solar cell with light transmission of claim 1, wherein said light-transmittance enhancing layer having a refractive index between 1 and 4.

5. The thin film solar cell with light transmission of claim 1, wherein each said light-transmittance region is further extended through said absorption layer by further removing part of said absorption layer down to a boundary level between said absorption layer and said front electrode layer.

6. The thin film solar cell with light transmission of claim 5, wherein each said light-transmittance region is further extended through said front electrode layer by removing part of said front electrode layer down to a level of said substrate.

7. The thin film solar cell with light transmission of claim 5, wherein said light-transmittance enhancing layer is formed of insulating material.

8. The thin film solar cell with light transmission of claim 1, wherein said encapsulation layer is formed of a material selected from the group consisting of ethylene vinyl acetate copolymer (EVA) and polyvinyl butyral (PVB).

9. The thin film solar cell with light transmission of claim 1, wherein said absorption layer is formed of a material selected from the group consisting of amorphous silicon (a-Si), polycrystalline silicon (poly-Si), microcrystalline silicon (mc-Si) and microcrystalline silicon germanium (mc-SiGe).

10. The thin film solar cell with light transmission of claim 1, wherein said absorption layer is formed of cadmium telluride (CdTe).

11. The thin film solar cell with light transmission of claim 1, wherein said front electrode layer is formed of transparent conducting oxide (TCO).

12. The thin film solar cell with light transmission of claim 10, wherein said TCO is selected from the group consisting of SnO2, ITO, IZO, AZO, BZO, GZO and ZnO.

13. The thin film solar cell with light transmission of claim 1, wherein said substrate is selected from the group consisting of glass, quartz, transparent plastics, transparent polymer and flexible substrate.

14. The thin film solar cell with light transmission of claim 1, wherein said substrate is a transparent glass substrate selected from the group consisting of soda lime glass (SLG), low iron class and alkali free glass.

15. The thin film solar cell with light transmission of claim 1, wherein said back electrode layer is formed of metal.

16. The thin film solar cell with light transmission of claim 15, wherein said metal is selected from the group consisting of aluminum (Al), nickel (Ni), gold (Au), silver (Ag), chromium (Cr), titanium (Ti) and palladium (Pd).
